(19) United States
(12) Patent Application Publication
(10) Pub. No.: US 2006/0086056 A1
(43) Pub. Date: Apr. 27, 2006

(54) Aqueous slurry composition for chemical mechanical planarization

(76) Inventor: Sang-Ick Lee, Suwon-si (KR)

Correspondence Address: David A. Einhorn, Esq.;Anderson Kill & Olick, P.C., 1251 Avenue of the Americas, New York, NY, 10020, US

(21) Appl. No.: 11/259,013

(22) Filed: Oct. 26, 2005

(30) Foreign Application Priority Data
Oct. 26, 2004 (KR) 10-2004-0085623

(51) Int. Cl. C09K 3/14; H01L 21/44

(52) U.S. Cl. 51/307; 438/669

(57) ABSTRACT

An aqueous slurry composition of the present invention, comprising a first polyacrylic acid and a second polyacrylic acid having specific weight average molecular weights ranging from 1,000,000 to 3,000,000 and from 2,000,000 to 8,000,000, respectively, in combination with a metal oxide abrasive, can perform highly efficient chemical mechanical planarization (CMP) of a layer formed during the manufacturing process of a multi-layered semiconductor device.

### FIELD OF THE INVENTION

The present invention relates to an improved aqueous slurry composition for chemical mechanical planarization (CMP) of a layer formed during the process of manufacturing a multi-layered semiconductor device.

### BACKGROUND OF THE INVENTION

It is vital to remove undesired step heights generated on a layer formed during the manufacture of a multi-layered semiconductor device by means of chemical mechanical planarization (CMP). The degree of planarity (DOP) achievable by such a CMP process is defined by formula, DOP=1−(SH_{f}/SHᵢ), wherein SHᵢ represents the initial step height before CMP, and SH_{f}, the final step height after CMP.

The planarizing process of an insulating layer deposited on a wafer having a pattern formed thereon, using a conventional slurry composition for CMP, is illustrated in FIGS. 1A to 1C. FIG. 1A shows a step height (SHᵢ) generated when growing an insulating layer (2) on a patterned part (1). In FIGS. 1B and 1C, the step height (SHᵢ) is gradually lowered by the action of abrasive particles (3) in the slurry composition forced by a polishing pad (4).

However, conventional slurry compositions for CMP have often failed to provide a DOP value of 0.9 or higher due to various factors. That is, after the completion of CMP, a step height (SH_{f}) corresponding to about 10% of the initial step height still remains, as shown in FIG. 1C. Such a step height remaining after polishing in the course of layer-forming steps of a semiconductor device with a design rule of 100 nm or less gives an insufficient margin in the subsequent exposure and etching steps for the prevention of bridge formation which leads to a reduced yield.

### SUMMARY OF THE INVENTION

Accordingly, it is an object of the present invention to provide an aqueous slurry composition having excellent planarization performance characteristics that can be advantageously used in chemical mechanical planarization (CMP) of a layer formed during the manufacturing process of a semiconductor device.

In accordance with one aspect of the present invention, there is provided an aqueous slurry composition for CMP which comprises;

1) 0.5 to 10% by weight of a metal oxide abrasive,

2) 0.01 to 5% by weight of a combination of a first polyacrylic acid, or a derivative thereof, having a weight average molecular weight ranging from 1,000,000 to 3,000,000 and a second polyacrylic acid, or a derivative thereof, having a weight average molecular weight ranging from 2,000,000 to 8,000,000; the weight average molecular weight of the first polyacrylic acid or its derivative being smaller by 500,000 or more than that of the second polyacrylic acid or its derivative, and

3) 0.1 to 2% by weight of a basic neutralizer;

wherein the first and second polyacrylic acids or derivatives thereof are allowed to interact with the abrasive to form a complex having a size of 100 to 5,000 nm.

### BRIEF DESCRIPTION OF THE DRAWINGS

The above and other objects and features of the present invention will become apparent from the following description of the invention, when taken in conjunction with the accompanying drawings, which respectively show:

FIGS. 1A to 1C: schematic diagrams illustrating a planarizing process of an insulating layer deposited on a wafer having a pattern formed thereon, by using a conventional slurry composition for CMP;

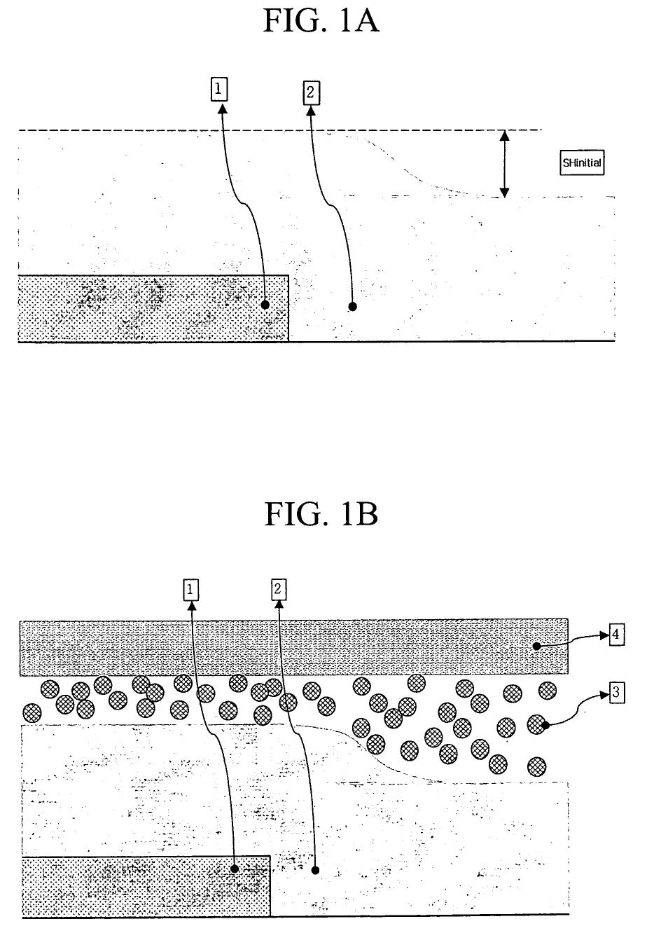

FIG. 2: a schematic diagram of a long-chain polyacrylic acid or a derivative thereof which is used in the present invention;

FIG. 3: a schematic diagram of a complex formed between metal oxide abrasive particles and polyacrylic acid; and

FIGS. 4A to 4D: schematic diagrams illustrating the planarizing process of an insulating layer deposited on a wafer having a pattern formed thereon, by using the inventive slurry composition for CMP.

1 patterned part

2: insulating layer

3: abrasive particles

4: polishing pad

5: abrasive-polymer complex

SHᵢ: step height before CPM

SH_{f}: step height after CPM using a conventional slurry composition

SH_{f}′: step height after CPM using the inventive slurry composition

### DETAILED DESCRIPTION OF THE INVENTION

The inventive slurry composition for CMP is characterized in that it comprises as a complexing agent two kinds of polyacrylic acid or derivatives thereof having specifically different weight average molecular weights, i.e., one having a weight average molecular weight ranging from 1,000,000 to 3,000,000, and the another, from 2,000,000 to 8,000,000, the former having a weight average molecular weight smaller by at least 500,000 than that of the latter.

The metal oxide abrasive used in the present invention may be one of any conventional materials used for CMP, and it may be selected from the group consisting of silica (SiO₂), alumina (Al₂O₃), ceria (CeO₂), zirconia (ZrO₂), titania (TiO₂), magnesia (MgO₂), ferric oxide (Fe₃O₄), hafnia (HfO₂) and a mixture thereof, preferably a ceria. The metal oxide may have a particle size ranging from 10 to 500 nm.

Said metal oxide abrasive is used in an amount ranging from 0.5 to 10% by weight. When its amount is less than 0.5% by weight, desired planarization effect cannot be achieved, and when its amount is more than 10% by weight, significant scratch generation occurs.

The inventive composition comprises as a complexing agent a combination of a first polyacrylic acid and a second polyacrylic acid, or a combination of derivatives thereof, having weight average molecular weights ranging from 1,000,000 to 3,000,000 and from 2,000,000 to 8,000,000, respectively, in an amount ranging from 0.01 to 5% by weight. It is noted that the weight average molecular weight of the first polyacrylic acid or derivative thereof should be smaller by 500,000 or more than that of the second polyacrylic acid or derivative thereof. Preferably, the weight ratio of the first and second polyacrylic acids or derivatives thereof in the inventive composition is in the range of 1:5˜10.

A suitable combination of CARBOPOLs(trade name), e.g., “CARBOPOL 940” and “CARBOPOL 941” available from Noveon Corporation, as well as their amine, nitrile, amide and sulfonate derivatives can be appropriately used in the present invention.

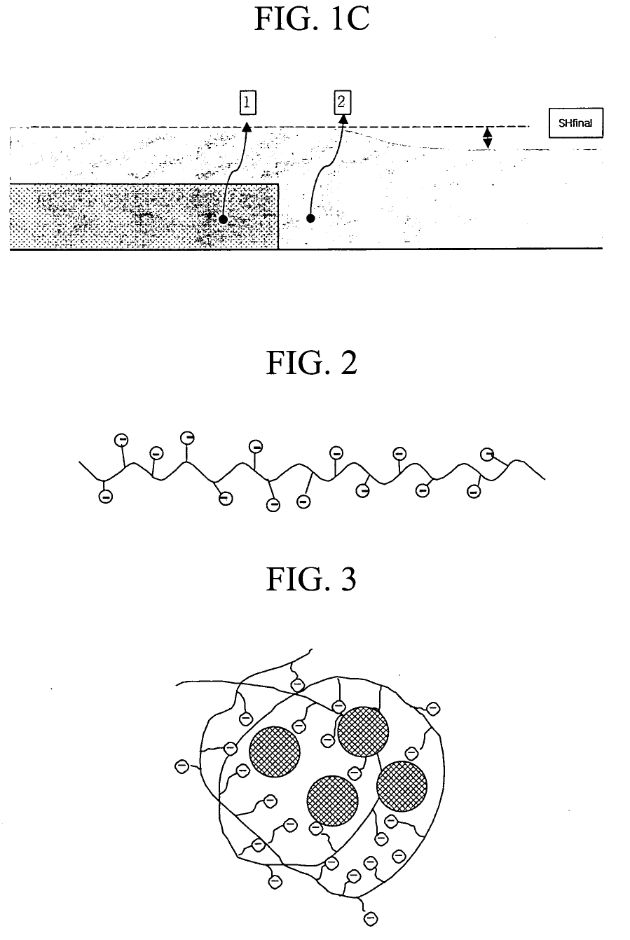

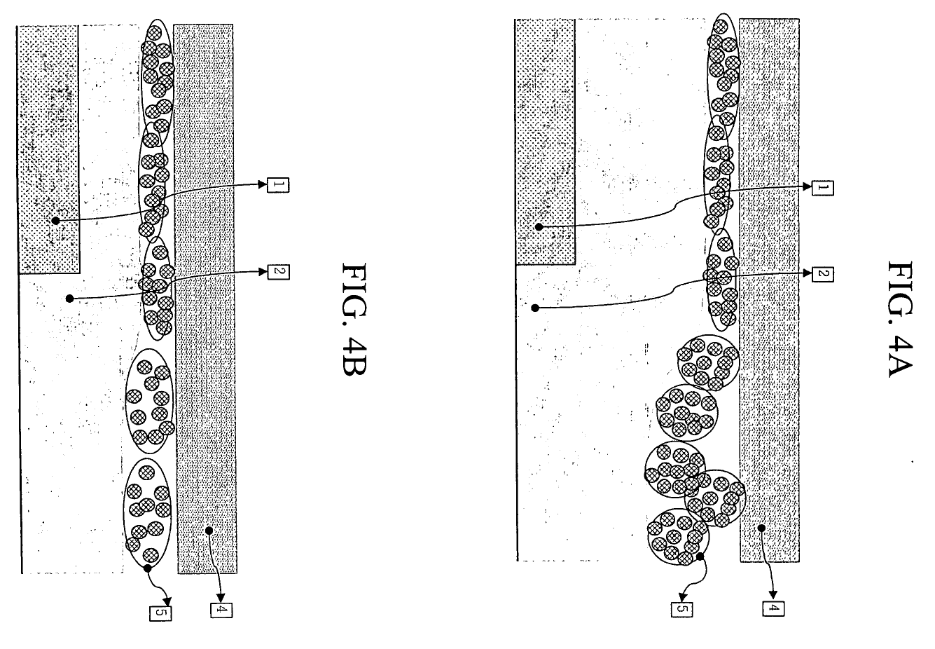

A polyacrylic acid or a derivative thereof is anionic due to the preponderant presence of carboxyl groups (—COOH), and it remains unfolded in the form of a long chain in an aqueous slurry, especially when alkaline, due to repulsive forces between anionic ions, as shown in FIG. 2. When brought into contact with abrasive metal oxide particles, such a polyacrylic acid or a derivative thereof forms a 100 to 5,000 nm-sized complex (abrasive-polymer complex), preferably a 200 to 1,000 nm-sized complex, together with the abrasive due to the attractive interaction between the polymer and the metal of the metal oxide abrasive, as shown in FIG. 3. In the complex, the abrasive particles are encapsulated by the polymeric compounds.

When applied to CMP of a layer having a significant step height, such an abrasive-polymer complex, e.g., of a spherical form, participates in the polishing process taking different forms depending on the regions of varying step heights. Specifically, at a region where the step height is high (i.e., the gap between the polishing surface and the polishing pad is small), the complex is pressurized by the action of the polishing pad and takes a flattened shape which has a higher abrasive capability than the original spherical shape due to the increased number of abrasive particles exposed and brought into contact with the polishing surface of the layer. On the other hand, at a region where the step height is low (i.e., the gap between the polishing surface and the polishing pad is wide), the complex maintains its original form close to a sphere having a reduced polishing capability.

The gist of the present invention lies in the realization that the degree of flattenization of the originally spherical abrasive-polymer complex by the shearing action of the polishing pad can be controlled by changing the chain-length, or the molecular weight, of the polymer. Thus, the present invention provides for the first time that a suitable combination of complexing polymers having different molecular weights is capable of achieving a DOP value which is much higher than that achievable by the previous disclosures in the art.

The basic neutralizer used in the present invention plays the role of increasing the activity of the polyacrylic acid or the derivative thereof present in the slurry, and representative examples thereof include potassium hydroxide, ammonium hydroxide, monoethanol amine, diethanol amine, triethanol amine and a mixture thereof. Said basic neutralizer is used in an amount ranging from 0.1 to 2% by weight to adjust the pH of the slurry composition to 4 to 9, preferably of 5 to 8.

Besides the above-mentioned components, the inventive slurry composition may further contain various additives which are conventionally used in the preparation of a slurry for CMP.

The aqueous slurry composition of the present invention may be prepared by mixing at room temperature the metal oxide abrasive, polyacrylic acid or derivative thereof, basic neutralizer and other optional additives with water.

In accordance with the present invention, CMP of a layer formed during the process of manufacturing a multi-layered semiconductor device is performed by providing the inventive aqueous slurry composition containing the abrasive-polyacrylic acid complex on the surface of the layer having a step height to be removed, and polishing the layer with a polishing means to remove the step height of the layer. The polishing may be conducted under a pressure of 1 to 10 psi and at a polishing pad rotating rate of 10 to 100 rpm.

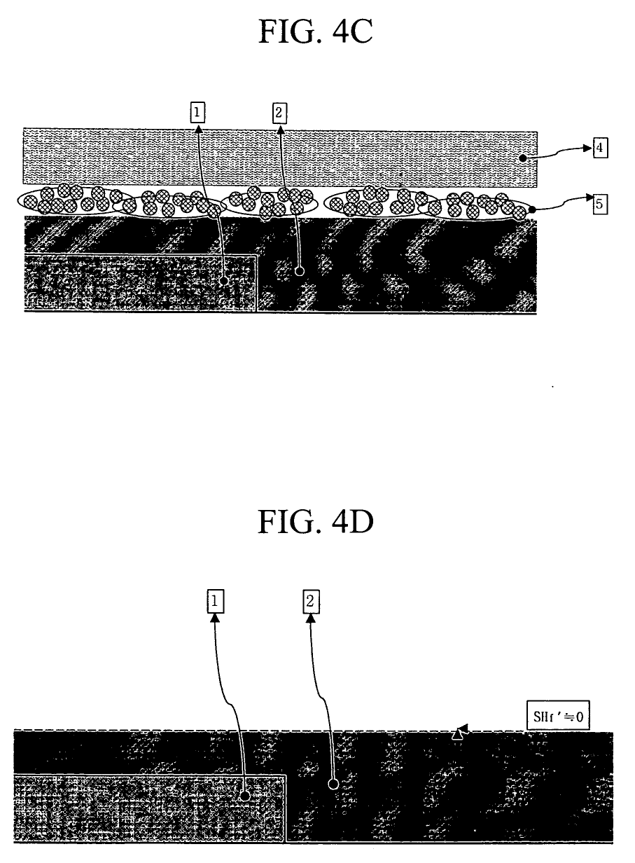

The process for planarizing an insulating layer deposited on a wafer having a patterned part, by using the inventive slurry composition is illustrated in FIGS. 4A to 4D. FIGS. 4A and 4B show that at the region where the step height of the insulating layer is high (i.e., the gap between the polishing surface and the polishing pad is narrow), more of the abrasive particles of the abrasive-polymer complex in the composition become exposed (because the complex becomes flatter) to achieve a high polishing rate; on the other hand, at the region where the step height thereof is low, the abrasive-polymer complex remains in its spherical form with a concomitant reduction in the polishing rate. After the step height of the insulating layer is completely removed, all of the abrasive-polymer complexes take the flattened shape over all the surface of the insulating layer, the abrasion rate drops markedly due to the increased friction resistance exerted by the increased number of abrasive particles present at the polishing interface, against the externally applied force by the polishing pad (auto-stop function of CMP) (see FIG. 4C). FIG. 4D illustrates a case wherein the original step height is completely removed and ideal planarization is achieved by CMP using the inventive slurry composition (SH_{f}′≈0).

As described above, the inventive slurry composition is capable of performing improved CMP over a large area, and therefore, it can be beneficially used in a CMP process of a layer formed during the manufacturing process of semiconductor devices, e.g., logic device, memory and non-memory, especially in shallow trench isolation (STI) CMP on the manufacture of Dynamic Random Access Memory (DRAM), interlayer dielectric (ILD), inter-metal dielectric (IMD) and metal CMP.

In case the layer of the semiconductor device to be polished is an insulating layer deposited on a wafer having a pattern formed thereon, it is preferred that the insulating layer has a thickness of no more than 4 folds of the depth of the pattern.

The following Examples are given for the purpose of illustration only, and are not intended to limit the scope of the invention.

### EXAMPLE 1

To an aqueous slurry containing 8% of silica particles having an average particle size of about 40 nm, both “CARBOPOL 940” and “CARBOPOL 941” (Noveon Corporation) having weight average molecular weights of 4,000,000 and 1,250,000, respectively, were added while stirring together with ammonium hydroxide such that the amounts of silica, CARBOPOL 940, CARBOPOL 941 and ammonium hydroxide of the resulting mixture became 7.5, 4.5, 0.5 and 1% by weight, respectively, based on the total amount of the mixture. The mixture was further stirred for 30 min for stabilization to obtain a silica aqueous slurry composition.

### EXAMPLE 2

To an aqueous slurry containing 5% of alumina particles having an average particle size of about 40 nm, both “CARBOPOL 940” and “CARBOPOL 941” having weight average molecular weights of 4,000,000 and 1,250,000, respectively, were added while stirring together with ammonium hydroxide and distilled water such that the amounts of alumina, CARBOPOL 940, CARBOPOL 941 and ammonium hydroxide of the resulting mixture became 4.5, 4.5, 0.5 and 1% by weight, respectively, based on the total amount of the mixture. The mixture was further stirred for 30 min for stabilization to obtain an alumina aqueous slurry composition.

### EXAMPLE 3

To an aqueous slurry containing 5% of ceria particles having an average particle size of about 40 nm, both “CARBOPOL 940” and “CARBOPOL 941” having weight average molecular weights of 4,000,000 and 1,250,000, respectively, were added while stirring together with ammonium hydroxide and distilled water such that the amounts of ceria, CARBOPOL 940, CARBOPOL 941 and ammonium hydroxide of the resulting mixture became 4.2, 4.5, 0.5 and 1% by weight, respectively, based on the total amount of the mixture. The mixture was further stirred for 30 min for stabilization to obtain a ceria aqueous slurry composition.

### EXAMPLE 4

To an aqueous slurry containing 1% of ceria particles having an average particle size of about 40 nm, both “CARBOPOL 940” and “CARBOPOL 941” having weight average molecular weights of 4,000,000 and 1,250,000, respectively, were added while stirring together with ammonium hydroxide and distilled water such that the amounts of ceria, CARBOPOL 940, CARBOPOL 941 and ammonium hydroxide of the resulting mixture became 0.9, 0.9, 0.1 and 1% by weight, respectively, based on the total amount of the mixture. The mixture was further stirred for 30 min for stabilization to obtain a ceria aqueous slurry composition.

### EXAMPLE 5

To an aqueous slurry containing 5% of ceria particles having an average particle size of about 40 nm, both “CARBOPOL 940” and “CARBOPOL 941” having weight average molecular weights of 4,000,000 and 1,250,000, respectively, were added while stirring together with potassium hydroxide and distilled water such that the amounts of ceria, CARBOPOL 940, CARBOPOL 941 and potassium hydroxide of the resulting mixture became 4.2, 4.5, 0.5 and 1% by weight, respectively, based on the total amount of the mixture. The mixture was further stirred for 30 min for stabilization to obtain a ceria aqueous slurry composition.

### EXAMPLE 6

To an aqueous slurry containing 5% of ceria particles having an average particle size of about 40 nm, both “CARBOPOL 940” and “CARBOPOL 941” having weight average molecular weights of 2,000,000 and 1,500,000, respectively, were added while stirring together with ammonium hydroxide and distilled water such that the amounts of ceria, CARBOPOL 940, CARBOPOL 941 and ammonium hydroxide of the resulting mixture became 4.3, 0.9, 0.1 and 2% by weight, respectively, based on the total amount of the mixture. The mixture was further stirred for 30 min for stabilization to obtain a ceria aqueous slurry composition.

### EXAMPLE 7

To an aqueous slurry containing 1% of ceria particles having an average particle size of about 40 nm, both “CARBOPOL 940” and “CARBOPOL 941” having weight average molecular weights of 3,000,000 and 2,000,000, respectively, were added while stirring together with potassium hydroxide and distilled water such that the amounts of ceria, CARBOPOL 940, CARBOPOL 941 and potassium hydroxide of the resulting mixture became 0.9, 0.9, 0.1 and 1% by weight, respectively, based on the total amount of the mixture. The mixture was further stirred for 30 min for stabilization to obtain a ceria aqueous slurry composition.

### EXAMPLE 8

To an aqueous slurry containing 5% of ceria particles having an average particle size of about 40 nm, both “CARBOPOL 940” and “CARBOPOL 941” having weight average molecular weights of 3,000,000 and 2,000,000, respectively, were added while stirring together with ammonium hydroxide and distilled water such that the amounts of ceria, CARBOPOL 940, CARBOPOL 941 and ammonium hydroxide of the resulting mixture became 4.7, 0.9, 0.1 and 1% by weight, respectively, based on the total amount of the mixture. The mixture was further stirred for 30 min for stabilization to obtain a ceria aqueous slurry composition.

### EXAMPLE 9

To an aqueous slurry containing 5% of ceria particles having an average particle size of about 40 nm, both “CARBOPOL 940” and “CARBOPOL 941” having weight average molecular weights of 3,000,000 and 2,000,000, respectively, were added while stirring together with ammonium hydroxide and distilled water such that the amounts of ceria, CARBOPOL 940, CARBOPOL 941 and ammonium hydroxide of the resulting mixture became 4.5, 3.6, 0.4 and 1% by weight, respectively, based on the total amount of the mixture. The mixture was further stirred for 30 min for stabilization to obtain a ceria aqueous slurry composition.

### EXAMPLE 10

To an aqueous slurry containing 10% of ceria particles having an average particle size of about 40 nm, both “CARBOPOL 940” and “CARBOPOL 941” having weight average molecular weights of 3,000,000 and 2,000,000, respectively, were added while stirring together with potassium hydroxide and distilled water such that the amounts of ceria, CARBOPOL 940, CARBOPOL 941 and potassium hydroxide of the resulting mixture became 8.7, 4.5, 0.5 and 2% by weight, respectively, based on the total amount of the mixture. The mixture was further stirred for 30 min for stabilization to obtain a ceria aqueous slurry composition.

### COMPARATIVE EXAMPLE 1

To an aqueous slurry containing 10% of silica particles having an average particle size of about 40 nm, a polyacrylic acid (Noveon Corporation) having a weight average molecular weight of 10,000 was added while stirring together with ammonium hydroxide and distilled water such that the amounts of silica, polyacrylic acid and ammonium hydroxide of the resulting mixture became 8.9, 5 and 1% by weight, respectively, based on the total amount of the mixture. The mixture was further stirred for 30 min for stabilization to obtain a silica aqueous slurry composition.

### COMPARATIVE EXAMPLE 2

To an aqueous slurry containing 5% of ceria particles having an average particle size of about 40 nm, a polyacrylic acid (Noveon Corporation) having a weight average molecular weight of 10,000 was added while stirring together with ammonium hydroxide and distilled water such that the amounts of ceria, polyacrylic acid and ammonium hydroxide of the resulting mixture became 4.5, 5 and 1% by weight, respectively, based on the total amount of the mixture. The mixture was further stirred for 30 min for stabilization to obtain a ceria aqueous slurry composition.

### COMPARATIVE EXAMPLE 3

To an aqueous slurry containing 5% of ceria particles having an average particle size of about 40 nm, a polyacrylic acid (Noveon Corporation) having a weight average molecular weight of 1,000,000 was added while stirring together with ammonium hydroxide and distilled water such that the amounts of ceria, polyacrylic acid and ammonium hydroxide of the resulting mixture became 4.5, 5 and 1% by weight, respectively, based on the total amount of the mixture. The mixture was further stirred for 30 min for stabilization to obtain a ceria aqueous slurry composition.

Evaluation of Degree of Planarity

A silicon dioxide insulating layer was formed on a silicon wafer having a 1 micron-depth pattern formed thereon to a thickness of 2 micron according to PE-TEOS (Plasma enhanced-tetraethyl orthosilicate) method to obtain a layer for polishing.

Then, using each of the slurry compositions obtained in Examples 1 to 10 and Comparative Examples 1 to 3, the layer for polishing was planarized with Mirra equipment (a product of AMAT Inc., USA) and IC1000/suba IV stacked pad (a product of Rodel Inc., USA) under a pressure of 3.5 psi and at a polishing pad rotating rate of 50 rpm for 1 min.

The degree of planarity (DOP) in accordance with such a CMP process using each of the slurry compositions was determined by formula, DOP=1−(SH_{f}/SHᵢ), wherein SHᵢ represents an initial step height before CMP, and SH_{f}, a final step height after CMP. The results are shown in Table 1.

TABLE 1

| | Degree of Planarity (DOP) |
|---|---|
| Example 1 | 0.92 |
| Example 2 | 0.93 |
| Example 3 | 0.95 |
| Example 4 | 0.97 |
| Example 5 | 0.93 |
| Example 6 | 0.96 |
| Example 7 | 0.94 |
| Example 8 | 0.96 |
| Example 9 | 0.97 |
| Example 10 | 0.98 |
| Comp. Ex. 1 | 0.68 |
| Comp. Ex. 2 | 0.72 |
| Comp. Ex. 3 | 0.79 |

As shown in Table 1, the inventive slurry compositions obtained in Example 1 to 10 give markedly improved DOP of 0.92 or higher, over the slurry compositions obtained in Comparative Examples 1 to 3.

As described above, the slurry composition in accordance with the present invention is capable of performing improved CMP over a large area, and therefore, it can be beneficially used in a CMP process of a layer formed during the manufacturing process of a semiconductor device.

While the invention has been described with respect to the above specific embodiments, it should be recognized that various modifications and changes may be made to the invention by those skilled in the art which also fall within the scope of the invention as defined by the appended claims.

What is claimed is:

1. An aqueous slurry composition for chemical mechanical planarization (CMP) which comprises;
1) 0.5 to 10% by weight of a metal oxide abrasive,
2) 0.01 to 5% by weight of a combination of a first polyacrylic acid, or a derivative thereof, having a weight average molecular weight ranging from 1,000,000 to 3,000,000 and a second polyacrylic acid, or a derivative thereof, having a weight average molecular weight ranging from 2,000,000 to 8,000,000; the weight average molecular weight of the first polyacrylic acid or its derivative being smaller by 500,000 or more than that of the second polyacrylic acid or its derivative, and
3) 0.1 to 2% by weight of a basic neutralizer;
wherein the first and second polyacrylic acids or derivatives thereof are allowed to interact with the abrasive to form a complex having a size of 100 to 5,000 nm.

2. The aqueous slurry composition of claim 1, wherein the abrasive is a metal oxide selected from the group consisting of silica (SiO₂), alumina (Al₂O₃), ceria (CeO₂), zirconia (ZrO₂), titania (TiO₂), magnesia (MgO₂), ferric oxide (Fe₃O₄), hafnia (HfO₂) and a mixture thereof

3. The aqueous slurry composition of claim 1, wherein the derivative of the first or second polyacrylic acid is selected from the group consisting of amine, nitrile, amide, sulfonate derivatives, and a mixture thereof

4. The aqueous slurry composition of claim 1, wherein the weight ratio of the amounts of the first and second polyacrylic acids, or derivatives thereof, is 1:5˜10.

5. The aqueous slurry composition of claim 1, wherein the basic neutralizer is selected from the group consisting of potassium hydroxide, ammonium hydroxide, monoethanol amine, diethanol amine, triethanol amine and a mixture thereof

6. The aqueous slurry composition of claim 1 whose pH is in the range of 4 to 9.

7. The aqueous slurry composition of claim 1, wherein the complex has a size of 200 to 1,000 nm.

8. A method for chemical mechanical planarization (CMP) of a layer with a step height formed during the manufacture of a multi-layered semiconductor device comprising; providing the aqueous slurry composition of claim 1 containing a complex of an abrasive and polyacrylic acid or a derivative thereof to the interface formed between the layer and a rotating polishing means, and polishing the layer to remove the step height of the layer.

9. The method of claim 8, wherein the polishing is conducted under a pressure of 1 to 10 psi and at a rotating rate of the polishing means of 10 to 100 rpm.

10. The method of claim 8 which is performed for shallow trench isolation (STI), interlayer dielectric (ILD), inter-metal dielectric (IMD) or metal CMP.

11. The method of claim 8, wherein the layer to be polished is an insulating layer deposited on a wafer having a patterned part formed thereon and the insulating layer has a thickness which is no more than 4 times of that of the patterned part.

12. The method of claim 8, wherein, during the polishing, the complex of the abrasive and the polyacrylic acid or derivative thereof takes a flattened shape at the region where the step height of the layer is high, and it maintains its original form close to a sphere at the region where the step height thereof is low.

13. The layer of a semiconductor device obtained by the method of claim 8.

14. The layer of claim 13 which has a planarity degree of 0.92 or higher.
